(19) United States
(12) Patent Application Publication
(10) Pub. No.: US 2025/0132781 A1
(43) Pub. Date: Apr. 24, 2025

(54) ELECTRONIC CIRCUIT AND DEVICE

(71) Applicant: STMicroelectronics International N.V., Geneva (CH)

(72) Inventors: Samia Ouyahia, Vernouillet (FR); Eric Wilhelm, Gisors (FR)

(21) Appl. No.: 18/920,542

(22) Filed: Oct. 18, 2024

(30) Foreign Application Priority Data
Oct. 20, 2023 (FR) 2311360

(51) Int. Cl. H04B 1/40; H03F 3/19; H03H 7/38

(52) U.S. Cl. CPC H04B 1/40; H03F 3/19; H03H 7/38; H03F 2200/451

(57) ABSTRACT

The present description relates to an electronic circuit having an impedance matching circuit comprising a first inductance coupling a first node to a second node, and a second inductance coupling the second node to a third node, the third node being coupled to ground. The first and second inductances are configured to form a positive magnetic coupling between each other.

### CROSS-REFERENCED TO RELATED APPLICATIONS

This application claims the priority benefit of French Patent Application No. 2311360, filed on Oct. 20, 2023, entitled “Circuit électronique,” which is hereby incorporated herein by reference to the maximum extent allowable by law.

### TECHNICAL FIELD

The present disclosure generally concerns electronic circuits, and devices comprising these electronic circuits, particularly radio frequency communication devices.

### BACKGROUND

Many electronic circuits and devices, particularly radio frequency communication devices, require impedance matching circuits between a bias circuit, coupled to a matching circuit, and an antenna. In certain cases, such as for example in test circuits, the bias circuit is coupled to the antenna. As a result, the impedance matching circuit then has to be modified to limit signal losses and costs.

### SUMMARY

There exists a need to provide a wide-band impedance matching circuit which limits signal losses and costs.

An embodiment overcomes all or part of the disadvantages of known electronic circuits.

An embodiment provides an electronic circuit having an impedance matching circuit comprising a first inductance coupling a first node to a second node, and a second inductance, coupling the second node to a third node, the third node being coupled to ground, the first and second inductances being configured to form a positive magnetic coupling between each other.

According to an embodiment, the third node is coupled to ground via a capacitive element.

According to an embodiment, the first and the second inductances are formed by planar conductive windings.

According to an embodiment, the second node is intended to be biased by a test device.

According to an embodiment, the third node is intended to be biased by a power supply of the electronic circuit.

According to an embodiment, the first node is intended to be coupled to an amplifier.

According to an embodiment, the magnetic coupling is greater than 0.5.

According to an embodiment, the first and the second inductance are configured so that a current can flow therethrough in the same direction.

According to an embodiment, the first inductance and the second inductance are stacked.

According to an embodiment, the second inductance has a number of windings greater than the number of windings of the first inductance.

According to an embodiment, one or a plurality of first conductive tracks, insulated from the second inductance, totally or partly surround an outer region of the winding of the second inductance.

According to an embodiment, one or a plurality of second conductive tracks, insulated from the second inductance, are arranged between a central portion of the second inductance which is not covered by a winding and an inner region of the winding of the second inductance.

According to an embodiment, one or a plurality of third conductive tracks, insulated from the first inductance, totally or partly surround an outer region of the winding of the first inductance.

According to an embodiment, one or a plurality of fourth conductive tracks, insulated from the first inductance, are arranged between a central portion of the winding of the first inductance which is not covered by a winding and an inner region of the winding of the first inductance.

According to an embodiment, the value of the capacitive element is configured to limit the occurrence of a current loop.

According to an embodiment, the impedance matching circuit comprises another capacitive element coupling the first and the second nodes.

According to an embodiment, the electromagnetic field generated by the first inductance and the electromagnetic field generated by the second inductance are superimposed in a same direction.

An embodiment provides an electronic device comprising the electronic circuit such as described hereabove, and an amplifier coupled to the first node.

In an embodiment, the device further comprises a test device configured to bias the second node.

In an embodiment, the test device is configured to bias the second node with a bias tee.

In an embodiment, the device further comprises an antenna coupled to the bias tee.

In an embodiment, the amplifier comprises a bipolar-type transistor and the first node is coupled to a collector of the transistor.

An embodiment provides a 5^{th} Generation (5G) radio frequency communication system comprising the electronic device such as described hereabove.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 very schematically shows an example of an electronic device;

FIG. 2 very schematically shows an electronic device according to an embodiment;

FIG. 3 shows the electronic device of FIG. 2 according to an embodiment;

FIG. 4 shows a top view of a portion of the electronic device of FIG. 3 according to an embodiment;

FIG. 5 shows a top view of another portion of the electronic device of FIG. 3 according to an embodiment;

FIG. 6 shows a combined cross-section view of the embodiments of FIGS. 4 and 5;

FIG. 7 shows simulations of the operation of the device of FIG. 3; and

FIG. 8 is an alternative embodiment of the circuit of FIG. 3.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. When two elements are magnetically coupled without contact, there will be specified “magnetic coupling”.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

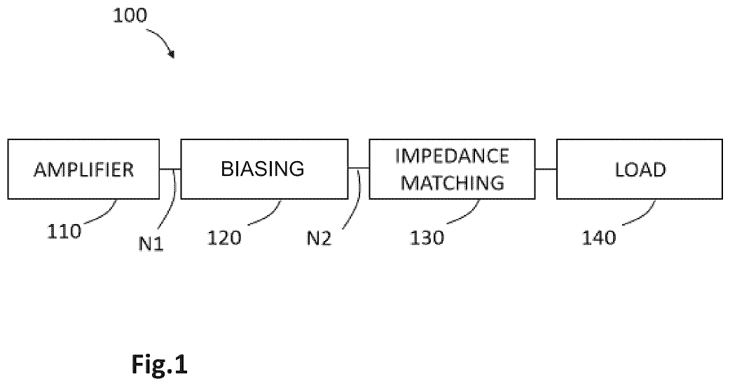

FIG. 1 very schematically shows an example of electronic device 100. Device 100 is for example a device used in a system processing radio frequencies.

Electronic device 100 comprises an amplification block 110 (AMPLIFIER) which for example comprises a CMOS or bipolar transistor. In the shown example, a biasing block 120 (BIASING) couples the amplification block 110 at a node N1 to an impedance matching circuit 130 (IMPEDANCE MATCHING) at a node N2. Impedance matching circuit 130 is itself coupled, preferably connected, to a load 140 (LOAD). Load 140 is for example a circuit comprising an antenna. In the case where amplification block 110 comprises a bipolar transistor, biasing block 120 is for example coupled, preferably connected, to the collector of this transistor. Biasing block 120 is for example formed of a bias tee comprising an inductance coupling a power supply rail to node N1 and of a capacitive element coupling node N1 to node N2.

The bias tee is for example used to power with a voltage or a current the device while enabling high speed and ultrawide band signals to flow, with a minimum degradation of the signal.

Impedance matching circuit 130 has the function of matching the output impedance of amplification block 110, which is for example 17 Ohms with a capacitance from 1 to 3 μF at an impedance of the load which is for example 50 Ohms without degrading the signal level.

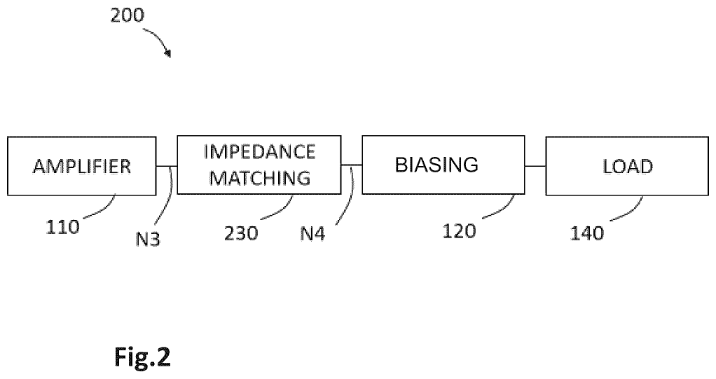

FIG. 2 very schematically shows an electronic device 200 according to an embodiment.

Device 200 is similar to device 100, except that an impedance matching circuit 230 is coupled, preferably connected, to amplification block 110 at a node N3 and to biasing block 120 at a node N4. Biasing block 120 this time couples load 140 to node N4 to allow a biasing of second node N4.

The architecture of device 200 is for example obtained when biasing block 120 and possibly load 140 are arranged on a circuit having a different substrate than impedance matching circuit 230 and/or amplification block 110. In an example, biasing block 120 and possibly load 140 are arranged on a test circuit. In another example, impedance matching circuit 130 and/or amplification block 110 are formed in a semiconductor substrate, for example a silicon substrate.

As compared with the example of FIG. 1, device 200 requires redefining a new architecture of impedance matching circuit 230 with no series capacitive element nor shunt inductance while limiting the surface area used. The constraints in terms of performance remain the same, such as for example matching the output impedance of amplification block 110, which is for example 17 Ohms with a capacitance from 1 to 3 μF at an impedance of the load which is for example 50 Ohms without degrading the signal and this, over a bandwidth for example greater than 1 GHz.

The described embodiments provide an impedance matching circuit comprising a first inductance coupling a first node to a second node, and a second inductance, coupling the second node to a third node which is coupled to ground, the first and second inductances being configured to form a positive magnetic coupling between each other.

In other words, the first and second inductances are configured so that the electromagnetic field generated by the first inductance and the electromagnetic field generated by the second inductance are superimposed in a same direction. This creates the positive magnetic coupling between the two inductances.

The described embodiments enable to do away with the use of capacitive elements in series and of shunt inductances while limiting the space used. The wideband transformation impedance is relatively flat and with low losses over a band of a plurality of GHz.

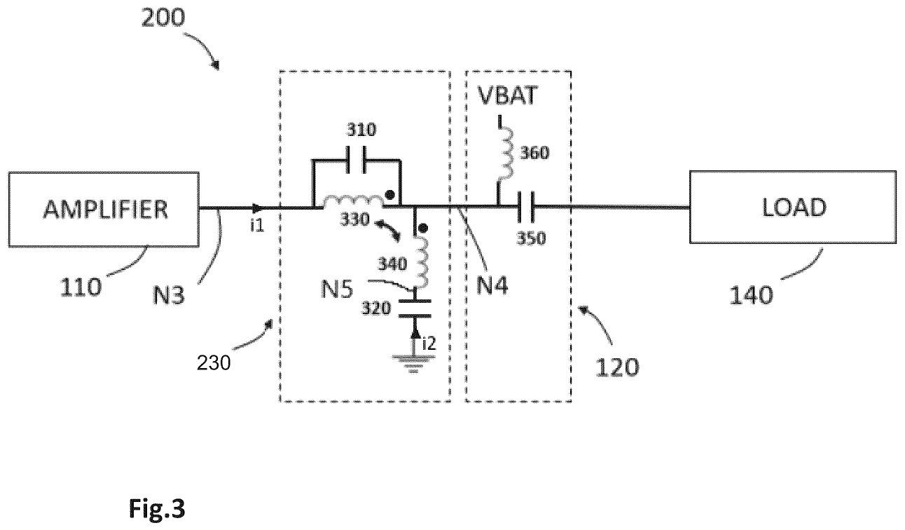

FIG. 3 shows the electronic device 200 of FIG. 2 according to an embodiment.

More precisely, FIG. 3 describes in detail an example of embodiment of impedance matching circuit 230 and of biasing block 120.

In the shown example, biasing block 120 is for example formed of a bias tee comprising an inductance 360 coupling a power supply rail VBAT to node N4 and of a capacitive element 350 coupling node N4 to load 140.

Impedance matching circuit 230 comprises a first inductance 330 coupling node N3 to node N4; and a second inductance 340, coupling node N4 to a node N5. The first and second inductances 330, 340 are thus connected at node N4.

In the shown example, where the biasing (that of biasing block 120) is external to circuit 230, a capacitive element 320 may be incorporated by coupling node N5 to ground. Capacitive element 320 is for example selected to limit the occurrence of a current loop, it has a value of several tens of picoFarads for example.

In an example, the impedance matching circuit further comprises an optional capacitive element 310 coupling nodes N3 and N4. Capacitive element 310 enables to obtain a flatter response over the entire bandwidth for example between 1 and 5 GHz. Capacitive element 310 has a value in the order of one μFarad for example.

In the shown example, the first and second inductances 330, 340 are configured to form a positive magnetic coupling between each other. For this purpose, the currents i1 and i2 respectively flowing through the two inductances 330, 340 flow in the same direction (that is, towards node N4). The electromagnetic fields generated by the first inductance and the second inductance can thus add if they are emitted at the same location.

The positive coupling is advantageous over a negative coupling since this limits the bandwidth and losses in the matching network.

A positive coupling as close as possible to 1 enables to limit losses and to gain efficiency while limiting the size of the inductances with respect to the circuit. For this purpose, it may be advantageous for the first and second inductances 330, 340 to be stacked on each other with for example a maximum overlapping between the windings of the first inductance 330 and those of the second inductance 340. This further enables to limit the encroachment of the inductances in the circuit.

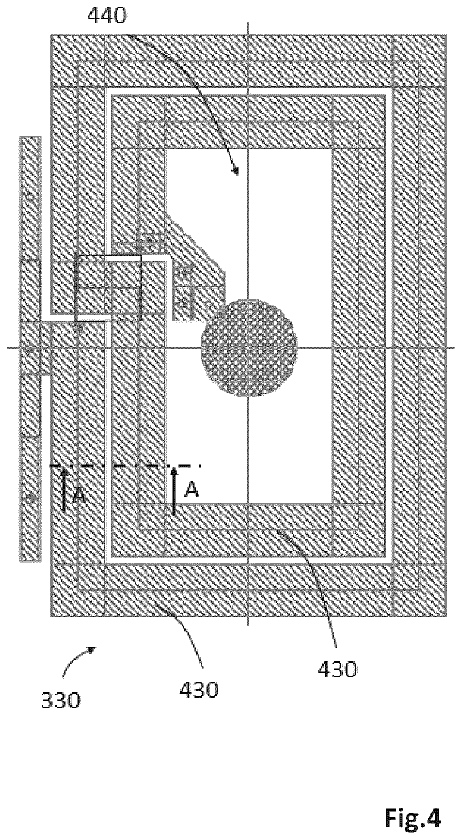

FIG. 4 shows a top view of a portion of the electronic device of FIG. 3 according to an embodiment. More particularly, FIG. 4 shows the magnetically-coupled lines of inductance 330, which form a primary portion of the magnetic coupling.

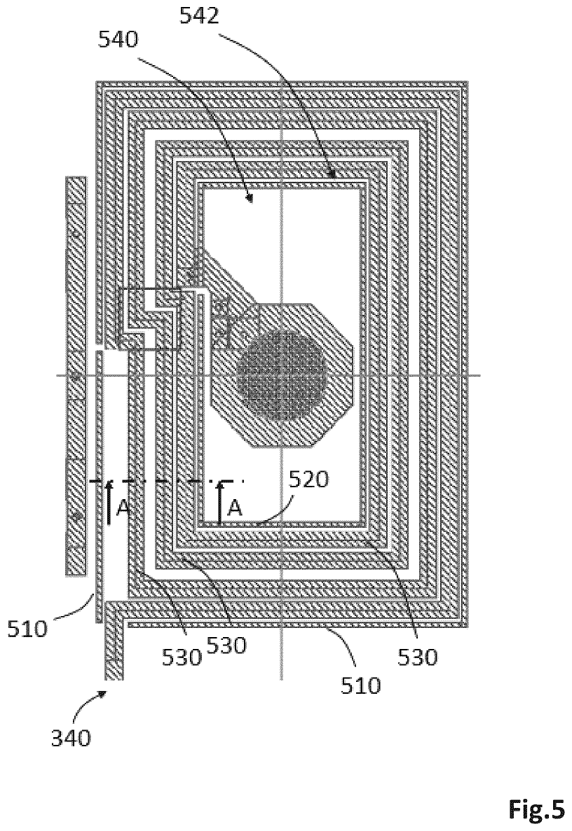

FIG. 5 shows a top view of another portion of the electronic device of FIG. 3 according to an embodiment. More particularly, FIG. 5 shows the magnetically-coupled lines of inductance 340, which form a secondary portion of the magnetic coupling.

More particularly, FIGS. 4 and 5 respectively illustrate, in top view, the first and second inductances 330, 340. Inductances 330 and 340 are shown separately for clarity but it is advantageous to stack them with a maximum overlapping.

In the shown examples, the first inductance 330 comprises two windings 430 and second inductance 340 comprises four windings 530. The length of the windings defines the value of the inductances. In an example, windings 430 have a width of approximately 30 μm and the windings have a width of approximately 10 μm. The width difference between windings 430 and 530 enables the two windings to be stacked along the most part of their length despite a large difference between their respective lengths. The innermost winding of the first inductance 330 is configured to have a track width which can be superimposed to the two innermost windings of the second inductance 340. The outermost winding of the first inductance 330 is configured to have a track width which can be superimposed to the two outermost windings of the second inductance 340.

In an example shown in FIG. 5, one or a plurality of conductive tracks 510, insulated from the second inductance 340, totally or partly surround an outer region of the winding of second inductance 340.

In another example shown in FIG. 5, one or a plurality of conductive tracks 520, insulated from the second inductance 340, are arranged between a central portion 540 of the second inductance 340 which is not covered with a winding and an inner region 542 of the inner winding of the second inductance.

In an example, not shown, one or a plurality of conductive tracks insulated from the first inductance 330, totally or partly surround an outer region of the winding of the first inductance 330.

In another example, not shown, one or a plurality of conductive tracks, insulated from the first inductance, are arranged between a central portion 440 of the first inductance 330 which is not covered with a winding and an inner region of the winding of the first inductance.

Tracks 510 and 520 are for example coupled to the first inductance 330 by vias.

Tracks 510 and 520 are, in another example, coupled to the tracks surrounding the windings of the first inductance by vias.

Tracks 510 and 520 enable to increase the positive magnetic coupling between inductances 330 and 340.

In an example, the first and second inductances 330, 340 are for example coupled by means of vias.

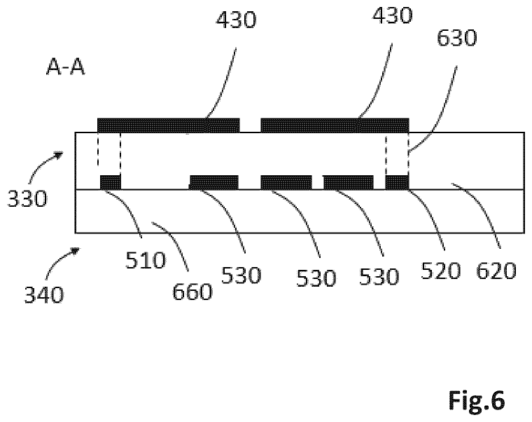

FIG. 6 shows a combined cross-section view A-A of the embodiments of FIGS. 4 and 5. More particularly, cross-section A-A is formed on a stack of the first and second inductances 330, 340. Cross-section A-A cuts one of tracks 510, and one of tracks 520, as well as three windings 530 of the second inductance located between these tracks 510 and 520. Cross-section A-A further shows the windings 430 of the first inductance 330 which are superimposed above the windings of inductance 340 shown in the cross-section.

In the shown example, the windings 530 of the second inductance 340 and tracks 510, 520 are formed by a metal deposition for example performed on a semiconductor substrate. The windings 530 of the second inductance 340 and tracks 510, 520 are for example coupled by an insulator 620. The windings 430 of the first inductance 330 are for example formed by a metal deposition performed inside and/or on top of insulator 620.

In the shown example, tracks 510 and 520 are for example coupled to the first inductance 330 by vias 630 formed through insulator 620. The positive magnetic coupling between the first and second inductances 330, 340 is thus reinforced.

By superimposing the first and second inductances 330 and 340, and by having a current flow in a same direction in these two inductances 330, 340, it is possible to obtain a positive magnetic coupling greater than 0.5 or even in the order of 0.9 with the use of tracks 510, 520.

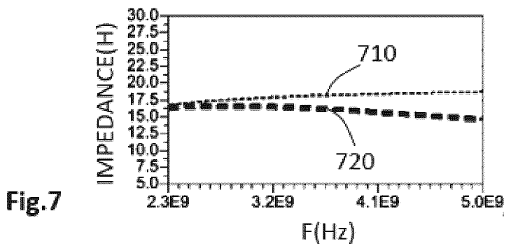

FIG. 7 shows simulations of the operation of the device of FIG. 3.

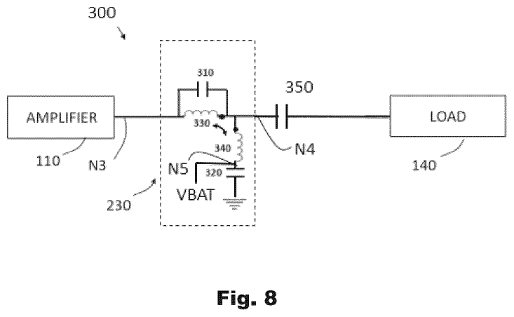

More particularly, FIG. 7 is a graph showing the impedance (IMPEDANCE) expressed in Henry, at node N3 according to the frequency between 2.3 and 5 GHZ, with (curve 720) and without (curve 710) optional capacitive element 310. In the example of FIGS. 7 and 8, capacitance 310 is in the order of 1 pF and inductances 330, 340 are similar to those of FIGS. 4 and 5 with a footprint, once stacked and in top view, of 330 μm by 230 μm.

With capacitive element 310, the impedance slightly decreases at high frequencies, which enables to keep a response at the output of the amplifier block flatter than without capacitive element 310.

FIG. 8 is an alternative embodiment of the circuit of FIG. 3. Circuit 300 of FIG. 8 is similar to the circuit of FIG. 3 except that the biasing voltage VBAT is generated by a power supply internal to the circuit 230, instead of being provided by the block 120, and is applied to node N5. Moreover, as compared to FIG. 3, in the example of FIG. 8, the inductance 360 is not implemented since the biasing is generated internally. For example, the power supply generating voltage VBAT is referenced to ground. In another example, the capacitive element 320 may be absent or of smaller size. The example of FIG. 8 allows cost and size reductions as compared to the example of FIG. 3 since the inductance 360 is not used.

Various embodiments and variants have been described. Those skilled in the art will understand that certain features of these various embodiments and variants may be combined, and other variants will occur to those skilled in the art. In particular, the number of windings of the first and second inductances 330, 340 as well as their width may be modified to optimize the positive magnetic coupling or adapt to the circuit constraints.

Finally, the practical implementation of the described embodiments and variants is within the abilities of those skilled in the art based on the functional indications given hereabove. In particular, regarding the overlapping of the first and second inductances, it may be adjusted by those skilled in the art to maximize the positive magnetic coupling between the two inductances 330 and 340.

The disclosed embodiments may for example be integrated in a 5G radio frequency communication system comprising electronic device 200.

1. An electronic circuit comprising:
an impedance matching circuit comprising:
a first inductance, coupled between a first node and a second node; and
a second inductance, coupled between the second node and a third node, wherein the third node is coupled to ground;
wherein the first and second inductances are configured to have a positive magnetic coupling between each other.

2. The electronic circuit according to claim 1, wherein the third node is coupled to the ground via a capacitive element.

3. The electronic circuit according to claim 1, wherein the first and the second inductances are formed by planar conductive windings.

4. The electronic circuit according to claim 1, wherein the second node is configured to be biased by a test device.

5. The electronic circuit according to claim 1, wherein the third node is configured to be biased by a power supply of the electronic circuit.

6. The electronic circuit according to claim 1, wherein the first node is configured to be coupled to an amplifier.

7. The electronic circuit according to claim 1, wherein the magnetic coupling is greater than 0.5.

8. The electronic circuit according to claim 1, wherein the first and the second inductances are configured for a current to flow there through in a same direction.

9. The electronic circuit according to claim 1, wherein the first inductance and the second inductance are stacked.

10. The electronic circuit according to claim 3, wherein the second inductance has a second number of windings greater than a first number of windings of the first inductance.

11. The electronic circuit according to claim 3, wherein one or more first conductive tracks, insulated from the second inductance, totally or partly surround an outer region of the winding of the second inductance.

12. The electronic circuit according to claim 3, wherein one or more second conductive tracks, insulated from the second inductance, are disposed between a central portion of the second inductance that is not covered by the winding of the second inductance, and an inner region of the winding of the second inductance.

13. The electronic circuit according to claim 3, wherein one or more third conductive tracks, insulated from the first inductance, totally or partly surround an outer region of the winding of the first inductance.

14. The electronic circuit according to claim 3, wherein one or more fourth conductive tracks, insulated from the first inductance, are disposed between a central portion of the first inductance that is not covered by the winding of the first inductance, and an inner region of the winding of the first inductance.

15. The electronic circuit according to claim 2, wherein a value of the capacitive element is configured to limit an occurrence of a current loop.

16. The electronic circuit according to claim 1, wherein the impedance matching circuit comprises another capacitive element coupling the first and the second nodes.

17. The electronic circuit according to claim 1, wherein a first electromagnetic field generated by the first inductance and a second electromagnetic field generated by the second inductance are superimposed in a same direction.

18. An electronic device comprising:
an electronic circuit having an impedance matching circuit comprising:
a first inductance, coupled between a first node and a second node; and
a second inductance, coupled between the second node and a third node, wherein the third node is coupled to ground;
wherein the first and second inductances are configured to have a positive magnetic coupling between each other; and
an amplifier coupled to the first node.

19. The electronic device according to claim 18, further comprising a test device configured to bias the second node.

20. The electronic device according to claim 19, wherein the test device is configured to bias the second node with a bias tee.

21. The electronic device according to claim 20, further comprising an antenna coupled to the bias tee.

22. The electronic device according to claim 18, wherein the amplifier comprises a bipolar-type transistor, and wherein the first node is coupled to a collector of the transistor.

23. A 5th Generation (5G) radio frequency communication system comprising:
an electronic circuit having an impedance matching circuit comprising:
a first inductance, coupled between a first node and a second node; and
a second inductance, coupled between the second node and a third node, wherein the third node is coupled to ground;
wherein the first and second inductances are configured to have a positive magnetic coupling between each other;
an amplifier coupled to the first node;
a test device configured to bias the second node with a bias tee; and
an antenna coupled to the bias tee.
